(19) United States
(12) Patent Application Publication
(10) Pub. No.: US 2024/0208035 A1
(43) Pub. Date: Jun. 27, 2024

(54) ACTUATOR, TILT CONTROL DEVICE, POSITIONING DEVICE, PROCESSING APPARATUS, AND DEVICE MANUFACTURING METHOD

(71) Applicant: SUMITOMO HEAVY INDUSTRIES, LTD., Tokyo (JP)

(72) Inventors: Ryuta NAKAJIMA, Yokosuka-shi (JP); Tatsuya YOSHIDA, Yokosuka-shi (JP)

(21) Appl. No.: 18/392,548

(22) Filed: Dec. 21, 2023

(30) Foreign Application Priority Data
Dec. 23, 2022 (JP) 2022-207569

(51) Int. Cl. B25H 1/10; A47B 13/08; F15B 15/20

(52) U.S. Cl. CPC B25H 1/10; A47B 13/081; F15B 15/20; A47B 2200/0043

(57) ABSTRACT

An actuator includes: a fixed part; a movable part; a drive unit that drives the movable part relative to the fixed part along a driving direction; a guide portion that extends in the driving direction in the fixed part and guides driving of the movable part by the drive unit along the driving direction; and a gas supply portion that supplies gas between the movable part and the guide portion, in which the guide portion is located at a center of the movable part when viewed in the driving direction.

### CROSS-REFERENCE TO RELATED APPLICATIONS

This application claims priority to Japanese Patent Application No. 2022-207569, filed on Dec. 23, 2022, which is incorporated by reference herein in its entirety.

### BACKGROUND

### Technical Field

Certain embodiments of the present invention relate to an actuator, a tilt control device, a positioning device, a processing apparatus, and a device manufacturing method.

### Description of Related Art

The related art discloses a linear motor. A magnet and a coil that configure a drive unit move relatively.

### SUMMARY

According to an embodiment of the present invention, there is provided an actuator including: a fixed part; a movable part; a drive unit that drives the movable part relative to the fixed part along a driving direction; a guide portion that extends in the driving direction in the fixed part and guides driving of the movable part by the drive unit along the driving direction; and a gas supply portion that supplies gas between the movable part and the guide portion. The guide portion is located at a center of the movable part when viewed in the driving direction.

According to another embodiment of the present invention, there is provided a tilt control device. The tilt control device includes a plurality of actuators that control a tilt of a driven body by driving a plurality of driven locations in the driven body. Each of the actuators includes a fixed part, a movable part that is located at the driven location, a drive unit that drives the movable part together with the driven location relative to the fixed part along a driving direction, and a guide portion that extends in the driving direction in the fixed part and guides driving of the movable part and the driven location by the drive unit along the driving direction. The guide portion is located at a center of the movable part when viewed in the driving direction.

According to still another embodiment of the present invention, there is provided a positioning device. The positioning device positions a table as a driven body whose tilt is controlled by the tilt control device described above.

According to still yet another embodiment of the present invention, there is provided a processing apparatus. The processing apparatus processes a workpiece placed on a table that is positioned by the positioning device described above.

According to still yet further another embodiment of the present invention, there is provided a device manufacturing method. The method includes manufacturing a device through processing of a workpiece using the processing apparatus described above.

### BRIEF DESCRIPTION OF THE DRAWINGS

FIG. 1 is a plan view schematically showing a stage device.

FIG. 2 is a perspective view showing a tilt control device.

FIG. 3 is a perspective sectional view showing an actuator.

FIG. 4 shows a modification example of the actuator.

### DETAILED DESCRIPTION

In the related art, a Z-axis guide and a Z-axis actuator are disposed to be physically separated from each other, so that there is a concern that smooth driving may be hindered at the time of driving of the linear motor.

It is desirable to provide an actuator and the like in which smoothness of driving can be improved.

According to an embodiment, the smoothness of driving by the drive unit can be improved due to the gas that is supplied between the movable part and the guide portion.

According to another embodiment, the tilt of the driven body can be appropriately controlled by the plurality of actuators.

Any combination of the above components or embodiments in which expressions of the components are converted in methods, devices, systems, recording mediums, computer programs, or the like are also included in the present invention.

Hereinafter, modes for carrying out the present invention (hereinafter also referred to as embodiments) will be described in detail with reference to the drawings. In the description and/or the drawings, identical or equivalent components, members, processing, and the like are denoted by the same reference numerals, and overlapping description thereof will be omitted. The scales or shapes of each part shown in the drawings are conveniently set to simplify the description, and should not be interpreted as being limited unless otherwise stated. The embodiments are exemplary and do not limit the scope of the present invention. All features or combinations thereof described in the embodiments are not necessarily essential to the present invention.

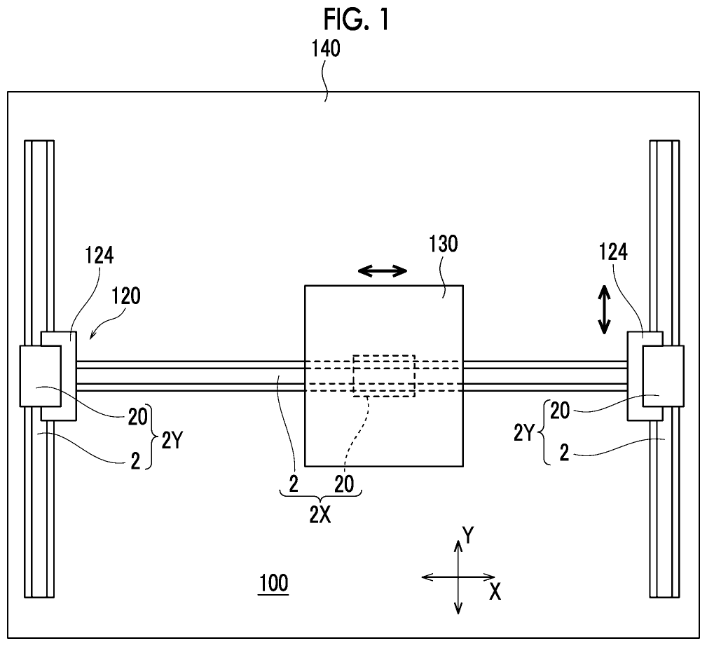

FIG. 1 is a plan view schematically showing a stage device 100 as a positioning device or a driving device to which an actuator and a tilt control device according to the present invention can be applied. The stage device 100 is an XY stage that positions a table as a driven body on which a workpiece such as a semiconductor wafer is placed in an X-axis direction (a right-left direction in FIG. 1) and a Y-axis direction (an up-down direction in FIG. 1). The stage device 100 includes a pair of Y-stages 120 that extend in the Y-axis direction and drive the table in the Y-axis direction, an X-stage 130 that is integrated with the table, extends in the X-axis direction, and drives the table in the X-axis direction, and a surface plate 140. The pair of Y-stages 120 are connected to both ends in the X-axis direction of the X-stage 130 through sliders 124. The Y-stages 120 and the X-stage 130 form an H shape when viewed from above.

At least the table, the Y-stage 120, and the X-stage 130 in the configuration of the stage device 100 may be accommodated in a vacuum chamber whose interior is maintained in a vacuum state. In the present specification, the terms “vacuum” refers to a state of a space filled with gas at pressure lower than normal atmospheric pressure. The vacuum can be classified into low vacuum (100 kPa to 100 Pa), medium vacuum (100 Pa to 0.1 Pa), high vacuum (0.1 Pa to 10⁻⁵ Pa), ultra-high vacuum (10⁻⁵ Pa to 10⁻⁸ Pa), extreme high vacuum (10⁻⁸ Pa or less), and the like according to a pressure region. The stage device 100 of the present embodiment may be used in any of the vacuum environments classified above. Further, the stage device 100 of the present embodiment may be used in a non-vacuum environment that does not fall within any of the above classifications.

The X-stage 130 and the Y-stage 120 are provided with linear motors 2X and 2Y, respectively. The linear power in the X-axis direction or the Y-axis direction which is generated by each of the linear motors 2X and 2Y linearly drives the table as a driven body in the X-axis direction or the Y-axis direction. The linear motor 2X, which is responsible for linear drive in the X-axis direction, includes an armature 2 that configures a stator and a track in the X-axis direction, and a movable element 20 that is movable in the X-axis direction along the armature 2. The table as a driven body is fixed to the movable element 20 and moves integrally therewith. Each of the pair of linear motors 2Y, which are responsible for linear drive in the Y-axis direction, includes an armature 2 that configures a stator and a track in the Y-axis direction, and a movable element 20 that is movable in the Y-axis direction along the armature 2. The slider 124 is fixed to the movable element 20 and moves integrally therewith. Here, since the pair of sliders 124 are connected to both ends of the armature 2 of the linear motor 2X, the pair of linear motors 2Y linearly drive the armature 2 of the linear motor 2X along with the pair of sliders 124 in the Y-axis direction. Then, since the table is present on the armature 2 (track) of the linear motor 2X, the pair of linear motors 2Y linearly drive the table in the Y-axis direction.

As described above, the stage device 100 (a positioning device using a linear motor as a power source) of the present embodiment that can realize highly accurate positioning or driving in both a vacuum environment and a non-vacuum environment is suitable for use in positioning or driving a table on which a semiconductor wafer or the like as a workpiece is placed, as a driven body, for example, in a semiconductor manufacturing apparatus such as exposure equipment, an ion implanter, heat treatment equipment, ashing equipment, sputtering equipment, dicing equipment, inspection equipment, or cleaning equipment, or a device manufacturing apparatus such as a flat panel display (FPD) manufacturing apparatus. The processing apparatus to which the stage device 100 of the present embodiment can be applied may be any apparatus that positions any workpiece to be processed by using the stage device 100 or the positioning device, and may be, for example, any manufacturing apparatus, any processing equipment (for example, a machine tool), or any inspection equipment.

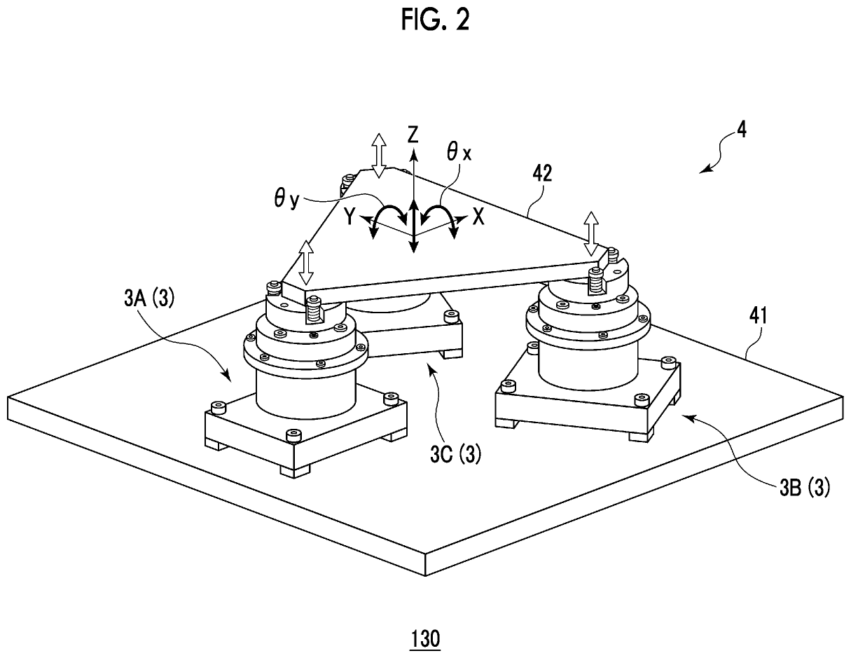

FIG. 2 is a perspective view showing a tilt control device 4 according to the present invention. The tilt control device 4 is provided between an upper surface (a surface in a +Z-axis direction) of the X-stage 130 (not shown) and a lower surface (a surface in a −Z-axis direction) of the table (not shown), and controls a tilt of the table as a driven body. The tilt control device 4 includes a fixed plate 41, three actuators 3A, 3B, and 3C (hereinafter also collectively referred to as an actuator 3) which are substantially the same, and a movable plate 42.

A lower surface of the fixed plate 41, which has a rectangular plate shape when viewed from above (when viewed in the Z-axis direction), is mounted on the upper surface of the X-stage 130. Further, on an upper surface of the fixed plate 41, the three actuators 3A, 3B, and 3C are provided at positions forming a substantially equilateral triangle when viewed from above. Each actuator 3 will be described later. A lower surface of the movable plate 42 is mounted on the upper surfaces of the three actuators 3A, 3B, and 3C. The movable plate 42 has a substantially equilateral triangular shape when viewed from above, and the three actuators 3A, 3B, and 3C are located at three vertices thereof. Each vertex of the movable plate 42 becomes each driven location that is driven along the Z-axis direction by each corresponding actuator 3.

A lower surface of the table as a driven body is mounted on an upper surface of the movable plate 42. Therefore, the table is driven integrally with the movable plate 42 by the three actuators 3A, 3B, and 3C. In other words, the table and the movable plate 42 configure a single driven body to be driven by the three actuators 3A, 3B, and 3C.

The three actuators 3A, 3B, and 3C drive the three driven locations in the driven body (the three vertices of the movable plate 42) along the Z-axis direction, thereby controlling a tilt of the driven body (the table and the movable plate 42). The tilt in the present embodiment means an angle θ that a normal line to the upper surface of the movable plate 42 as a driven body makes with the +Z-axis direction (typically, the vertical direction). As schematically shown in FIG. 2, the tilt θ is decomposed into two components, that is, a tilt (or rotation) θₓ around the X-axis and a tilt (or rotation) θ_{y} around the Y-axis.

In addition to such two-axis rotational drive (θₓ and θ_{y}), the three actuators 3A, 3B, and 3C can perform translational drive of the entirety of the movable plate 42 and the table in the Z-axis direction. The amount of translational drive is expressed as Z. In this manner, in the tilt control device 4 according to the present embodiment, three parameters (θₓ , θ_{y} , and Z) are controlled by the three actuators 3A, 3B, and 3C. Two actuators 3 are sufficient to realize tilt control only by two-axis rotational drive (θₓ and θ_{y}) without performing the translational drive in the Z-axis direction. In this case, any one of the three actuators 3A, 3B, and 3C in FIG. 2 may be replaced with a support stand that only supports one vertex of the movable plate 42 from below.

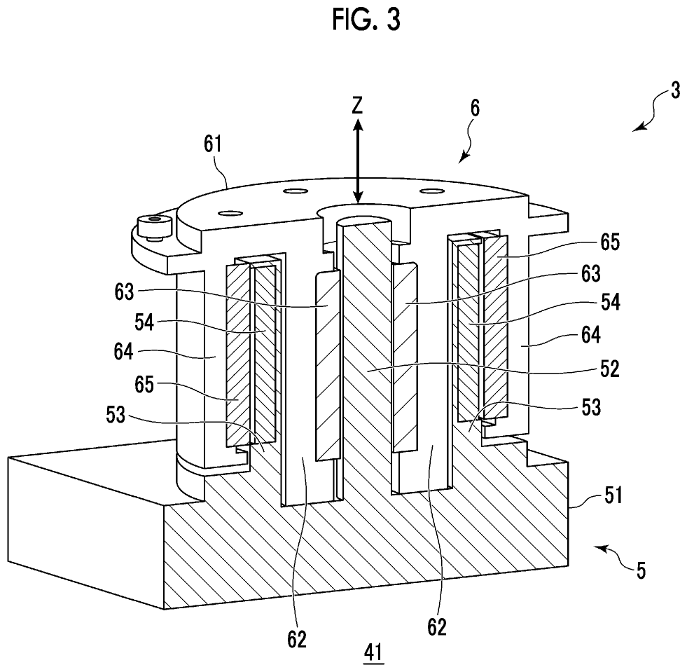

FIG. 3 is a perspective sectional view showing the actuator 3 according to the present invention. The actuator 3 includes a fixed part 5 and a movable part 6 that are relatively movable along the Z-axis direction as a driving direction. The movable part 6 is located at the driven location in the driven body (for example, the vertex of the movable plate 42 in FIG. 2).

A base portion 51 of the fixed part 5 is mounted on the fixed plate 41 of the tilt control device 4. A shaft-shaped or columnar guide portion 52 that extends in the +Z-axis direction toward the movable part 6 on the upper side is provided on an upper surface of the base portion 51. Further, on the upper surface of the base portion 51, a cylindrical motor installation portion 53 that extends in the +Z-axis direction toward the movable part 6 on the upper side is provided so as to surround the guide portion 52 in an annular shape or a circular ring shape when viewed in the driving direction (when viewed in the Z-axis direction). When viewed in the driving direction, the circular guide portion 52 and the circular ring-shaped motor installation portion 53 are disposed concentrically. One or a plurality of coils 54 that configure a motor such as a voice coil motor as a drive unit are provided on the outer periphery side of the motor installation portion 53 when viewed in the driving direction.

The movable part 6 having a substantially columnar outer shape includes a top portion 61 having a substantially disc shape when viewed in the driving direction. A cylindrical bearing portion 62 that extends in the −Z-axis direction toward the fixed part 5 on the lower side is provided on a lower surface of the top portion 61. When viewed in the driving direction, the circular ring-shaped bearing portion 62 surrounds the circular guide portion 52 with substantially no gap. One or a plurality of bearings 63 are provided on a surface of the bearing portion 62, which faces the guide portion 52 on the inner periphery side when viewed in the driving direction. The bearing 63, which surrounds the guide portion 52 with substantially no gap when viewed in the driving direction, axially supports the shaft-shaped guide portion 52 when the movable part 6 is driven relative to the fixed part 5 along the Z-axis direction. It is preferable that the bearing 63 axially supports the guide portion 52 in a manner that does not prevent the relative movement along the Z-axis direction between the bearing 63 and the guide portion 52. For example, the bearing 63 is configured as a rolling bearing having a plurality of rolling elements such as balls that are rotatable on a contact surface or a sliding surface with the guide portion 52.

A cylindrical motor installation portion 64 that extends in the −Z-axis direction toward the fixed part 5 on the lower side is provided on the lower surface of the top portion 61 so as to surround the bearing portion 62 in an annular shape or a circular ring shape when viewed in the driving direction. When viewed in the driving direction, the relatively small circular ring-shaped bearing portion 62 and the relatively large circular ring-shaped motor installation portion 64 are disposed concentrically. Further, when viewed in the driving direction, the circular guide portion 52 of the fixed part 5 is concentrically disposed within the circular ring-shaped bearing portion 62, and the circular ring-shaped motor installation portion 53 of the fixed part 5 is concentrically disposed between the circular ring-shaped motor installation portion 64 and the circular ring-shaped bearing portion 62. That is, the guide portion 52, the bearing portion 62, the motor installation portion 53, and the motor installation portion 64, which are disposed in order from the inner periphery side when viewed in the driving direction, are all disposed concentrically.

One or a plurality of permanent magnets 65, which configure a motor such as a voice coil motor together with the one or a plurality of coils 54, are provided on a surface of the motor installation portion 64, which faces the one or a plurality of coils 54 on the inner periphery side when viewed in the driving direction. In this manner, a drive unit such as a voice coil motor that is configured by the coil 54 in the fixed part 5 and the permanent magnet 65 in the movable part 6 drives the movable part 6 relative to the fixed part 5 along the driving direction (the Z-axis direction). Specifically, a magnetic field that is generated by a drive current flowing through the coil 54 exerts linear power in the Z-axis direction on the permanent magnet 65. In order to configure a similar drive unit, the coil 54 may be provided in the movable part 6 and the permanent magnet 65 may be provided in the fixed part 5.

When the movable part 6 is driven by the drive unit, the guide portion 52 that is located at the center of the movable part 6 when viewed in the driving direction guides the driving of the movable part 6 along the driving direction. Since the center axis of the movable part 6 and the shaft-shaped guide portion 52 substantially coincide with each other, the movable part 6 can be stably driven by the drive unit while the posture or balance of the movable part 6 is effectively maintained by the guide portion 52. Further, since the generation of unnecessary power in a circumferential direction or a radial direction can be effectively suppressed by the drive unit (the coil 54 and the permanent magnet 65) that annularly surrounds the guide portion 52 when viewed in the driving direction, the movable part 6 can be linearly driven with high accuracy along the Z-axis direction.

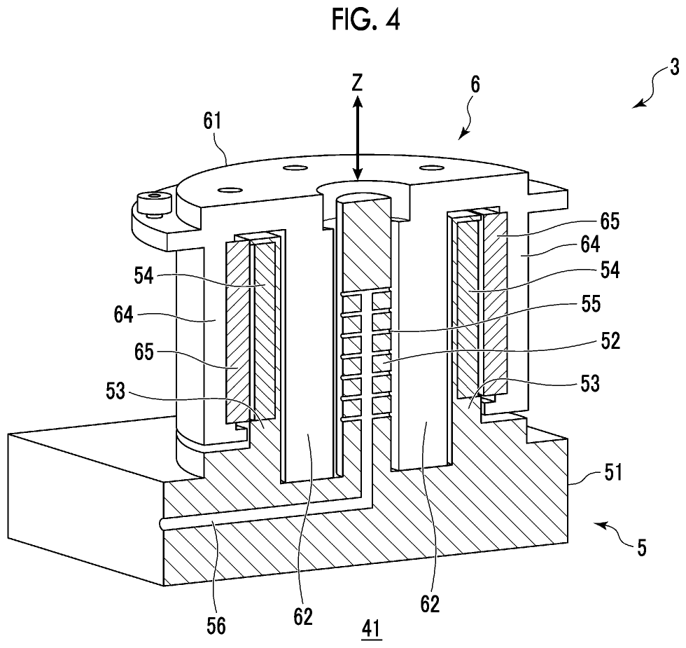

FIG. 4 shows a modification example of the actuator 3 shown in FIG. 3. In this modification example, instead of the contact type bearing 63 such as a rolling bearing in FIG. 3, a gas supply portion 55 that configures a non-contact type bearing is provided. The gas supply portion 55 supplies gas such as compressed air between the inner peripheral surface of the bearing portion 62 in the movable part 6 and the outer peripheral surface of the guide portion 52 in the fixed part 5. Due to the gas that is supplied by the gas supply portion 55, the movable part 6 (the bearing portion 62) can smoothly move with substantially non-contact with the guide portion 52 even while the movable part 6 (the bearing portion 62) is guided in the Z-axis direction by the guide portion 52.

As schematically shown in FIG. 4, it is preferable that the gas that is ejected between the bearing portion 62 and the guide portion 52 by the gas supply portion 55 is supplied through an air supply path 56 provided in the interior of the fixed part 5 (the base portion 51 and the guide portion 52). Further, with regard to the actuator 3 that is used in a vacuum environment, it is preferable to adopt an airtight structure that prevents the gas that is supplied between the bearing portion 62 and the guide portion 52 by the gas supply portion 55 from leaking out of the actuator 3. Further, it is preferable that an exhaust path for exhausting the gas supplied between the bearing portion 62 and the guide portion 52 by the gas supply portion 55 to the atmosphere or the like is provided in the interior of the fixed part 5 similarly to the air supply path 56.

The present invention has been described above based on the embodiments. Various modification examples are possible in the combinations of each component and each process in the embodiment provided as an example, and it is obvious to those skilled in the art that such modification examples are included in the scope of the present invention.

The configuration, operation, and function of each device or each method described in the embodiments can be realized by hardware resources or software resources, or by cooperation of hardware resources and software resources. As the hardware resources, for example, a processor, a ROM, a RAM, and various integrated circuits can be used. As the software resources, for example, programs such as an operating system and an application can be used.

It should be understood that the invention is not limited to the above-described embodiment, but may be modified into various forms on the basis of the spirit of the invention. Additionally, the modifications are included in the scope of the invention.

What is claimed is:

1. An actuator comprising:
a fixed part;
a movable part;
a drive unit that drives the movable part relative to the fixed part along a driving direction;
a guide portion that extends in the driving direction in the fixed part and guides driving of the movable part by the drive unit along the driving direction; and
a gas supply portion that supplies gas between the movable part and the guide portion,
wherein the guide portion is located at a center of the movable part when viewed in the driving direction.

2. The actuator according to claim 1, wherein the drive unit annularly surrounds the guide portion when viewed in the driving direction.

3. A tilt control device comprising:
a plurality of actuators that control a tilt of a driven body by driving a plurality of driven locations in the driven body,
wherein each of the actuators includes
a fixed part,
a movable part that is located at the driven location,
a drive unit that drives the movable part together with the driven location relative to the fixed part along a driving direction, and
a guide portion that extends in the driving direction in the fixed part and guides driving of the movable part and the driven location by the drive unit along the driving direction,
wherein the guide portion is located at a center of the movable part when viewed in the driving direction.

4. The tilt control device according to claim 3, wherein each of the actuators includes a gas supply portion that supplies gas between the movable part and the guide portion.

5. The tilt control device according to claim 3, wherein the drive unit annularly surrounds the guide portion when viewed in the driving direction.

6. The tilt control device according to claim 3, wherein at least three actuators are provided.

7. A positioning device for positioning a table as the driven body whose tilt is controlled by the tilt control device according to claim 3.

8. A processing apparatus for processing a workpiece placed on the table that is positioned by the positioning device according to claim 7.

9. A device manufacturing method comprising: manufacturing a device through processing of the workpiece using the processing apparatus according to claim 8.
